(19) United States
(12) Patent Application Publication
(10) Pub. No.: US 2026/0159373 A1
(43) Pub. Date: Jun. 11, 2026

(54) SPRING ASSEMBLY, SCANNING MIRROR, AND LIDAR SYSTEM

(71) Applicant: inSync Resonance Inc, Fremont, CA (US)

(72) Inventor: Qin ZHOU, Fremont, CA (US)

(21) Appl. No.: 18/970,964

(22) Filed: Dec. 6, 2024

(51) Int. Cl. B81B 3/00; F16F 1/373; F16F 1/48; G01S 7/481; G02B 26/08; G02B 26/10

(52) U.S. Cl. CPC B81B 3/0051; F16F 1/3737; F16F 1/48; G01S 7/4817; G02B 26/0833; G02B 26/105; B81B 2201/042; B81B 2203/0154

(57) ABSTRACT

A spring assembly, a scanning mirror, and a LiDAR system are provided, which relate to the technical field of mechanical manufacturing. The spring assembly includes: two torsion springs; and a coupling spring arranged between the two torsion springs, two ends of the coupling spring being connected to the two torsion springs, respectively. In response to the two torsion springs being twisted, the coupling spring being stretched to provide a torque that is non-linearly recovered. Technical solutions of the present disclosure can realize implementation schemes of a controllable non-linear torsion spring and a scanning mirror and a LiDAR system that are each based on the controllable non-linear torsion spring.

### FIELD

The present disclosure relates to the technical field of mechanical manufacturing, and more particularly, to a spring assembly, a scanning mirror, and a laser detection and ranging (LiDAR) system.

### BACKGROUND

A spring is a mechanical component that is widely used in mechanical products. A simple spring can be a rod having an end fixed and another end providing a restoring force during deformation. Similar simple springs are usually linear springs. That is, the restoring force of the spring is proportional to the deformation of the spring, The deformation includes, but is not limited to, a displacement and a torsion angle. However, in some application scenarios, a non-linear spring is preferred.

A micro-electro-mechanical system (MEMS) is a manufacturing technology platform developed based on semiconductor manufacturing technology. In the MEMS, springs are also required to be manufactured, which are also usually linear springs like those in the general mechanical field. One application of the MEMS is to manufacture a MEMS scanning mirror. Typically, the MEMS scanning mirror is composed of a multi-faceted micro-mirror. The multi-faceted micro-mirror is synchronously rotatable to achieve the effect of a larger scanning mirror. The spring is configured to control the multi-faceted micro-mirror to rotate. The related technologies, such as U.S. Pat. No. 11,085,995B2, reveal that the use of the non-linear spring can better synchronize the rotation of the multi-faceted micro-mirror. However, it is difficult to obtain a suitable implementation scheme for the non-linear spring either in the general mechanical field or in the MEMS.

### SUMMARY

The present disclosure aims to solve at least one of the technical problems in the related technologies. To this end, the present disclosure provides a spring assembly, a scanning mirror, and a LiDAR system, capable of realizing implementation schemes of a controllable non-linear torsion spring and a scanning mirror and a LiDAR system that each are based on the controllable non-linear torsion spring.

In a first aspect, the present disclosure provides a spring assembly. The spring assembly includes: two torsion springs; and a coupling spring arranged between the two torsion springs. Two ends of the coupling spring are connected to the two torsion springs, respectively, and in response to the two torsion springs being twisted, the coupling spring is stretched to provide a torque that is non-linearly recovered. The spring assembly obtained using the technical solution is equivalent to the controllable non-linear torsion spring.

In some embodiments, a method for connecting the two torsion springs and the coupling spring can be implemented as that each of the two torsion springs includes two fixing piles arranged opposite to each other and a first beam structure arranged between the two fixing piles. The first beam structure is provided with a first connecting plate, and the two ends of the coupling spring in a stretching direction are connected to two first connecting plates of the two torsion springs, respectively.

In some embodiments, in response to the two torsion springs being twisted, the first connecting plate is rotatable around a connection line between the two fixing piles arranged opposite to each other.

In some embodiments, the coupling spring includes a second connecting plate that is overhung, each of two ends of the second connecting plate has a first opening. The coupling spring further includes a second beam structure formed in the first opening. The first connecting plate is connected to the second connecting plate by the second beam structure. Therefore, the coupling spring is connected to the two torsion springs.

In some embodiments, an end of each of the two first connecting plates close to the coupling spring has a second opening. The coupling spring includes a connecting rod and two connecting beams arranged at two ends of the connecting rod, respectively. The connecting rod is connected to parts of each of the two first connecting plates arranged at two sides of the second opening by the two connecting beams, respectively. Therefore, the coupling spring is connected to the two torsion springs. In addition, such a connection method facilitates miniaturization of a size of the coupling spring, enlarging areas of the two torsion springs. In particular, in an embodiment in which a reflection mirror is arranged at a surface of each of the two first connecting plates of the two torsion springs, an effective reflection area of the reflection mirror can be efficiently enlarged.

In some embodiments, each of the two connecting beams can include a first bent portion protruding in a direction away from the connecting rod. This bent design of the connecting beam can realize that when the connecting beam receives a tensile force in a direction opposite to a protrusion direction of the first bent portion, a tensile stress of the connecting beam is unlikely to rapidly increase even if a large displacement occurs. Therefore, the first bent portion is prevented from fracturing the connecting beam in response to rapidly reaching a fracture stress of silicon, providing the first bent portion with resistance to fracture. In addition, the first bent portion also causes a recovery coefficient of the connecting beam to include a second-order non-linear recovery coefficient, which is conducive to ultimately realizing the controllable nonlinearity of the spring assembly.

In some embodiments, a drive unit is further arranged at the MEMS, the drive unit is configured to drive at least one of the two torsion springs to twist.

In some embodiments, two drive units are provided for the two torsion springs, respectively. The two drive units are configured to drive the two torsion springs to twist, respectively.

In some embodiments, the two drive units are configured to drive the two torsion springs to twist synchronously.

In a second aspect, a scanning mirror is provided according to the present disclosure. The scanning mirror includes torsion springs arranged in an array on a MEMS. A coupling spring is arranged between any two adjacent torsion springs of the torsion springs. Two ends of the coupling spring are connected to the two adjacent torsion springs, respectively, and in response to the two adjacent torsion springs being twisted, the coupling spring is stretched to provide a torque that is non-linearly recovered. Each of the torsion springs includes two fixing piles arranged opposite to each other and a beam structure arranged between the two fixing piles. The beam structure is provided with a first connecting plate. The two ends of the coupling spring in a stretching direction are connected to two first connecting plates of the two adjacent torsion springs, respectively. A reflection mirror is arranged at a surface of the first connecting plate.

In the scanning mirror according to the embodiments of the present disclosure, the reflection mirror is arranged at the first connecting plate of each torsion spring, in such a manner that each torsion spring is equivalent to one reflection mirror. In this case, a plurality of small-area reflection mirrors arranged in an array can be formed into a large-area scanning mirror. A specific scanning function can be realized by the torsion springs. Since the coupling spring is arranged between any two adjacent torsion springs, a plurality of spring assemblies, each of which is the spring assembly according to any of the above-mentioned embodiments, connected to each other are formed. Each spring assembly is equivalent to one controllable non-linear spring. In this case, other drive components can be used to drive the torsion springs to twist and to drive the reflection mirror to twist. Then, the torsion springs are recovered through a non-linear restoring force. Therefore, the above-mentioned actions are periodically completed, realizing that all the light emitted by the reflection mirrors is scanned in a predetermined region to achieve an effect of one overall scanning mirror.

In some embodiments, an end of each of the two first connecting plates of the two adjacent torsion springs that is close to the coupling spring has an opening. The coupling spring includes a connecting rod and two connecting beams arranged at two ends of the connecting rod, respectively. The connecting rod is connected to parts of each of the two first connecting plates arranged at two sides of the opening by the two connecting beams, respectively. This implementation scheme facilitates the miniaturization of the size of the coupling spring, enlarging areas of the torsion springs, especially efficiently enlarging the effective reflection area of the reflection mirror.

In some embodiments, each of the two connecting beams includes a first bent portion protruding in a direction away from the connecting rod. As mentioned above, this bent design of the connecting beam can realize that when the connecting beam receives the tensile force in the direction opposite to the protrusion direction of the first bent portion, the tensile stress of the connecting beam is unlikely to rapidly increase even if the large displacement occurs. Therefore, the first bent portion is prevented from fracturing the connecting beam in response to rapidly reaching the fracture stress of silicon, providing the first bent portion with the resistance to fracture. In addition, the first bent portion also causes the recovery coefficient of the connecting beam to include the second-order non-linear recovery coefficient, which is conducive to ultimately realizing the controllable nonlinearity of the spring assembly.

In some embodiments, the scanning mirror further includes a drive component configured to drive the torsion springs arranged in the array to twist synchronously.

In some embodiments, a drive component includes a plurality of drive units, each of the plurality of drive units is arranged corresponding to one of the torsion springs and is configured to drive the respective torsion spring to twist.

With the scanning mirror according to the embodiments of the present disclosure, the torsion springs and the coupling spring can form the spring assembly according to any of the above-mentioned embodiments, and thus reference to a design concept thereof can be made to contents in any of the embodiments of the spring assembly.

In a third aspect, a LiDAR system is further provided according to an embodiment of the present disclosure. The LiDAR system includes a light source, a photodetector, a processor, and the above-mentioned scanning mirror. A laser beam emitted by the light source is reflected to a target region by the scanning mirror. The photodetector is configured to receive at least part of the reflected light from the target region and convert the at least part of the reflected light into an electrical signal. The processor is configured to obtain a laser point cloud from the target region based on the electrical signal.

The scanning mirror according to the embodiments of the present disclosure and the torsion springs and the coupling spring that are arranged in the scanning mirror can form the spring assembly according to any of the above-mentioned embodiments, and thus reference to a design concept and corresponding technical effects thereof can be made to the contents described in any of the above-mentioned embodiments related to the spring assembly and the scanning mirror.

Additional aspects and advantages of the present disclosure will be provided at least in part in the following description or will become apparent at least in part from the following description or can be learned from practicing of the present disclosure.

### BRIEF DESCRIPTION OF THE DRAWINGS

The above and/or additional aspects and advantages of the present disclosure will become more apparent and more understandable from the following description of embodiments taken in conjunction with the accompanying drawings.

FIG. 1 is a schematic structural view of a torsion spring in the related technologies.

FIG. 2 is a schematic view of a spring assembly according to an embodiment of the present disclosure.

FIG. 3 is a schematic view of a torsion spring, according to the embodiment shown in FIG. 2, that is twisted.

FIG. 4 is a schematic structural view of a spring assembly according to an embodiment of the present disclosure.

FIG. 5 is a schematic structural view of a variation of the spring assembly shown in FIG. 4.

FIG. 6 is a schematic structural view of another spring assembly according to an embodiment of the present disclosure.

FIG. 7 is a schematic structural view of a variation of the spring assembly shown in FIG. 6.

FIG. 8 is a schematic structural view of yet another spring assembly according to an embodiment of the present disclosure.

FIG. 9 is a schematic structural view of a variation of the spring assembly shown in FIG. 8.

FIG. 10 is a schematic structural view of still yet another spring assembly according to an embodiment of the present disclosure.

FIG. 11 is a schematic structural view of a variation of the spring assembly shown in FIG. 10.

FIG. 12 is a schematic structural view of a scanning mirror according to an embodiment of the present disclosure.

FIG. 13 is a schematic structural view of a LiDAR system according to an embodiment of the present disclosure.

FIG. 14 is a schematic structural view of another LiDAR system according to an embodiment of the present disclosure.

### DETAILED DESCRIPTION

Embodiments of the present disclosure will be described in detail below with reference to examples thereof as shown in the accompanying drawings, throughout which same or similar elements, or elements having same or similar functions, are denoted by same or similar reference numerals. The embodiments described below with reference to the drawings are illustrative and are only intended to explain, rather than limit, the present disclosure.

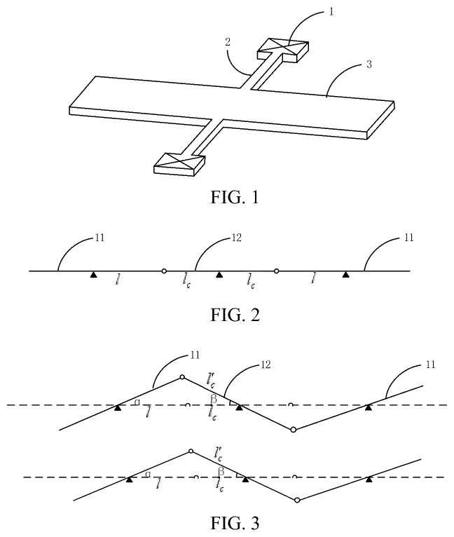

Springs used in the related technologies are mostly linear springs. That is, the coefficients of recovery of the springs are mostly first-order coefficients. FIG. 1 is a schematic structural view of a torsion spring in the related technologies. As shown in FIG. 1, the torsion spring includes two fixing piles 1. A beam structure 2 is arranged between the two fixing piles 1. In another exemplary embodiment of the present disclosure, a rigid plate 3 may be arranged at the beam structure 2 as desired. The torsion spring can be twisted around a connection line between the two fixing piles 1. Usually, a torsion restoring force of the torsion spring is proportional to a torsion angle of the torsion spring. That is, a coefficient of torsion is a first-order linear coefficient. However, there is a great demand for non-linear springs in some practical application scenarios. For example, in an application scenario of a MEMS-based scanning mirror, a drive component is required for driving a plurality of small-area reflection mirrors to twist simultaneously to serve as a mirror having a large area. When the plurality of small-area reflection mirrors is driven to twist synchronously, providing a non-linear restoring force for each small-area reflection mirror using a non-linear spring achieves a satisfactory synchronization effect. However, it is difficult to implement the non-linear spring on the MEMS.

The embodiments of the present disclosure provide an implementation scheme for a controllable non-linear spring through arranging a coupling spring between two torsion springs. Two ends of the coupling spring are connected to the two torsion springs, respectively. The coupling spring is stretched when the two torsion springs are twisted. In this case, the coupling spring can provide a tensile restoring force. The tensile restoring force, when applied to the two torsion springs, can serve as a torsion restoring force for the torsion springs and provides a torque that is non-linearly recovered, in such a manner that a recovery coefficient of an entire spring assembly is ultimately changed, which is equivalent to obtaining a torsion spring having a non-linear recovery coefficient.

FIG. 2 is a schematic view of a spring assembly according to an embodiment of the present disclosure, which presents a specific scheme for implementing one non-linear torsion spring using two torsion springs and one coupling spring. In an exemplary embodiment of the present disclosure, as shown in FIG. 2, the spring assembly includes two torsion springs 11. A coupling spring 12 is arranged between the two torsion springs 11. Two ends of the coupling spring 12 are connected to the two torsion springs 11, respectively. In addition, in response to the two torsion springs 11 being twisted, the coupling spring 12 can be driven to be stretched to provide a torque that is non-linearly recovered.

FIG. 3 is a schematic view of a torsion spring, according to the embodiment shown in FIG. 2, that is twisted. As shown in FIG. 3, a torsion angle of the torsion spring 11, when twisted, is α, and a torsion angle of the coupling spring 12, when twisted, is β. A distance from the center point of the torsion spring 11 to a junction point between the center point of the torsion spring 11 and the coupling spring 12 is referred to as a length l of the torsion spring. A distance from the center point of the coupling spring to the junction point is referred to as a length l_{c} of the coupling spring 12. The length l_{c} is an original length of the coupling spring. In addition, after the torsion spring 11 is stretched by torsion, the coupling spring 12 has a stretching length of l′_{c}, and an elongation in this process is Δl_{c}. For the case shown in FIG. 3, when the length l′_{c} of the coupling spring 12 that is stretched satisfies the following equation:

$${l}_{c}^{′} = \sqrt{{( {l}_{c} + l - l cos α )}^{2} + {( l sin α )}^{2}} ,$$

the above-mentioned equation can be simplified, using small-angle approximations, i.e.,

$$sin α = α and cos α = 1 - \frac{{α}^{2}}{2} , as :$$

$${l}_{c}^{′} = \sqrt{{( {l}_{c} + l {α}^{2} / 2 )}^{2} + {l}^{2} {α}^{2}} .$$

High-order terms in the above-mentioned equation are neglected to obtain the following result:

$${l}_{c}^{′} = \sqrt{{l}_{c}^{2} + {l}_{c} l {α}^{2} + {l}^{2} {α}^{2}} .$$

A Taylor expansion is performed on the above-mentioned equation and a term α² is retained to obtain:

$${l}_{c}^{′} = {l}_{c} + \frac{l {α}^{2}}{2} + \frac{{l}^{2} {α}^{2}}{2 {l}_{c}} = {l}_{c} + \frac{l ( l + {l}_{c} ) {α}^{2}}{2 {l}_{c}^{2}} {l}_{c} .$$

Therefore, it can be concluded that the elongation of the coupling spring 12 can be expressed as:

$$Δ {l}_{c} = \frac{l ( l + {l}_{c} ) {α}^{2}}{2 {l}_{c}^{2}} {l}_{c} .$$

In this case, a ratio γ of the length l of the torsion spring 11 to the original length l_{c} of the coupling spring 12 can be defined as:

$$γ = l / {l}_{c} .$$

Further, a calculation formula of the above-mentioned Δl_{c} can be simplified as:

$$Δ {l}_{c} = \frac{γ ( γ + 1 )}{2} {α}^{2} {l}_{c} .$$

The coupling spring 12 is elongated due to being stretched, and thus a restoring force F in a length direction of the coupling spring 12 is provided. If a tensile restoring coefficient of the coupling spring 12 is κ, a restoring torque caused by the elongation of the coupling spring 12 due to being stretched can be expressed as:

$$T = Fl sin ( α + β ) \approx Δ {l}_{c} kl sin ( γ + 1 ) α \approx \frac{γ ( γ + 1 )}{2} {α}^{2} {l}_{c} kl ( γ + 1 ) α = \frac{{( γ + 1 )}^{2}}{2} {kl}^{2} {α}^{3} .$$

Therefore, it can be seen that the restoring torque provided for the torsion spring 11 by the coupling spring 12 due to being stretched is non-linear, contains no linear term, and is proportional to α³.

In the above-mentioned embodiments of the present disclosure, even if the coupling spring 12 is a linear spring, i.e., the recovery coefficient k is a linear recovery coefficient, the recovery coefficient of the spring assembly obtained through arranging the coupling spring 12 between the two torsion springs based on the method according to the embodiments of the present disclosure is also non-linear, which is equivalent to obtaining one torsion spring having the non-linear recovery coefficient.

In addition, if the above-mentioned coupling spring 12 is a non-linear spring, i.e., k is the non-linear recovery coefficient, a degree of non-linearity of the whole spring assembly is obvious. Also, the degree of non-linearity of the spring assembly can be adjusted by adjusting the length of the torsion spring 11, a length of the coupling spring 12, and a recovery coefficient of the coupling spring 12, such as adjusting values of parameters such as γ, κ, and l. If the coupling spring 12 itself is set as non-linear, e.g., the recovery coefficient includes a first-order non-linear term h₁, a second-order non-linear term k₂, and a third-order non-linear term k₃, or the like, the recovery force F of the coupling spring in this case can be set as:

$$F = {k}_{1} Δ {l}_{c} + {k}_{2} Δ {l}_{c}^{2} + {k}_{3} Δ {l}_{c}^{3} + ⋯ .$$

With this scheme, a spring assembly with high-order non-linear terms can be obtained.

In the embodiments of the present disclosure, settings of the above-mentioned parameters in the coupling spring such as γ, κ, and I can realize adjusting the non-linear recovery coefficient of the spring assembly to obtain an adjustable non-linear torsion spring. A specific value of each parameter can be set as desired.

According to the embodiments of the present disclosure, a technical solution for realizing the adjustable non-linear torsion spring is provided. In the technical solution, a specific structure of the coupling spring is not limited, which can be designed as desired based on different application fields and application scenarios, as long as basic requirements of the above-mentioned embodiments can be satisfied. For example, the coupling spring having the two ends connected to the torsion spring, respectively, is stretchable in response to the torsion spring being twisted and can generate the tensile restoring force.

In some embodiments, the spring assembly according to any of the above-mentioned embodiments can be applied to the field of MEMS, and more particularly, to an MEMS scanning mirror. In this case, the two torsion springs 11 and the coupling spring 12 that are needed for the spring assembly can be formed at the MEMS while making a mutual position relationship, a connection relationship, or the like thereof conform to limits in the above-mentioned embodiments.

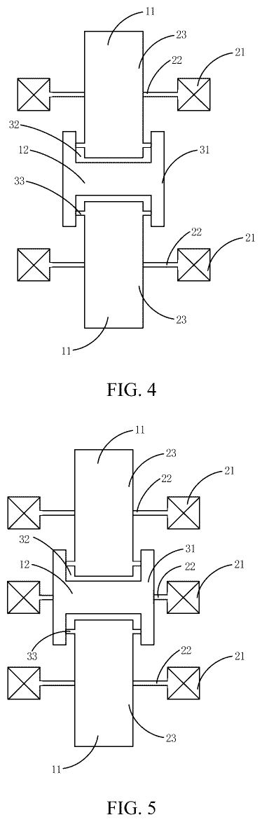

For the spring assembly arranged at the MEMS system, a specific structure of the spring assembly may be shown in FIG. 4 and FIG. 5. Each torsion spring 11 includes two fixing piles 21 arranged opposite to each other and a first beam structure 22 arranged between the two fixing piles 21. The first beam structure 22 is provided with a first connecting plate 23. The two ends of the coupling spring 12 in a stretching direction are connected to two first connecting plates 23 of the above-mentioned two torsion springs 11.

In this case, in response to the two torsion springs 11 being twisted, the first connecting plate 23 is rotatable around a connection line between the two fixing piles 21 arranged opposite to each other. The two ends of the coupling spring 12 are connected to parts of each of the two first connecting plates 23 of the two torsion springs 11, respectively. Therefore, the coupling spring 12 is stretched.

A specific structure of the coupling spring 12 and a connection relationship between the coupling spring 12 and the two torsion springs 11 are not limited in the embodiments of the present disclosure. In addition, two optional implementations are provided.

One embodiment may be as shown in FIG. 4. As shown in FIG. 4, the coupling spring 12 includes a second connecting plate 31 that is overhung. Each of two ends of the second connecting plate 31 has a first opening 32. A second beam structure 33 is formed in the first opening 32. The first connecting plate 23 is connected to the second connecting plate 31 by the second beam structure 33. A connection between the second beam structure 33 and the second connecting plate 31 is also equivalent to one fixing pile, to fix the first connecting plate 23 to the second connecting plate 31 by the second beam structure 33. With the above-mentioned method, the two ends of the coupling spring 12 are connected to the torsion spring 11. In addition, in response to the torsion spring 11 being twisted, the coupling spring 12 can be stretched, and more particularly, the second beam structure 33 can be stretched.

Another implementation may be as shown in FIG. 5. Compared with the second connecting plate 31 in FIG. 4, the second connecting plate 31 in FIG. 5 is free. In the embodiments of the present disclosure, the above-mentioned fixing pile 21 and the first beam structure 22 are further arranged at the second connecting plate 31. For the spring assembly arranged at the MEMS system, the above-mentioned fixing pile 21 may be arranged at a body of the MEMS system.

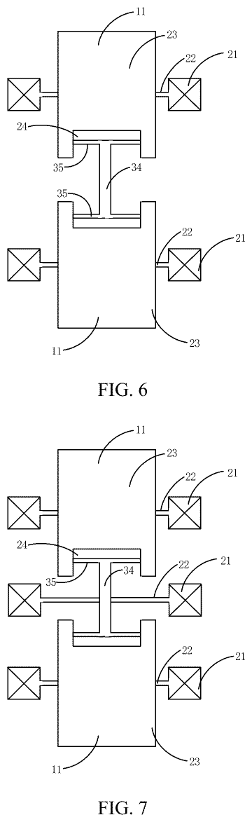

The other implementation may be as shown in FIG. 6, an end of each of the two first connecting plate 23 close to the coupling spring 12 has a second opening 24. The coupling spring 12 includes a connecting rod 34 and two connecting beams 35 arranged at two ends of the connecting rod 34, respectively. The connecting rod 34 is connected to parts of each of the two first connecting plates 23 arranged at two sides of the second opening 24 by the two connecting beams 35, respectively. The connecting beam 35 according to the embodiments of the present disclosure can also be regarded as a type of beam structure. A connection between the connecting beam 35 and the first connecting plate 23 can be regarded as the fixing pile for supporting the connecting beam 35. Since the two ends of connecting beam 35 are connected to the two first connecting plate 23, respectively, the connecting beam 35 may also be referred to as a double clamping beam.

According to the embodiment shown in FIG. 6, the torsion spring 11 and the coupling spring 12 can be connected. In addition, a main structure of the coupling spring 12 according to the embodiment can be regarded as being composed of one connecting rod 34 and the two connecting beams 35 arranged at the two ends of the connecting rod 34. The above-mentioned main structure can be made small.

In addition, when used as the MEMS scanning mirror, the above-mentioned structure at the MEMS can be realized through arranging a reflection mirror at a surface of the first connecting plate 23 of the torsion spring. In an exemplary embodiment of the present disclosure, the reflection mirror can be formed through applying a reflective material to the surface of the first connecting plate 22. In the embodiment shown in FIG. 6, making the coupling spring 12 (connecting rod 34) small reserves more space for accommodating the first connecting plate 23, in such a manner that an area of the reflection mirror at the connecting plate 23 is enlarged, enlarging an effective reflection area of the MEMS scanning mirror.

Another implementation may be as shown in FIG. 7. Compared with the connecting rod 34 in FIG. 6, the connecting rod 34 in FIG. 7 is free. In the embodiments of the present disclosure, the above-mentioned fixing pile 21 and the first beam structure 22 may be further arranged at the connecting rod 34. For the spring assembly arranged at the MEMS system, the above-mentioned fixing pile 21 may be arranged at the body of the MEMS system.

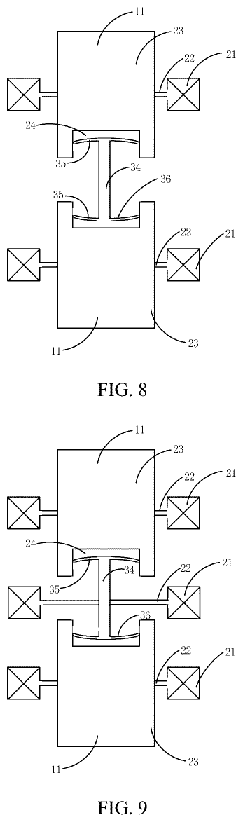

In some embodiments, the connecting beam 35 in the coupling spring 12 shown in FIG. 6 may be designed to be curved in shape. That is, the connecting beam 35 at least includes a first bent portion 36. FIG. 8 is a schematic structural view of a specific coupling spring according to an embodiment of the present disclosure. As shown in FIG. 8, the coupling spring includes the connecting rod 34 and the two connecting beams 35 arranged at the two ends of the connecting rod 34, respectively. In addition, the first bent portion 36 is arranged at the connecting beam 35.

In particular, the first bent portion 36 may be arranged in a variety of methods. For example, as shown in FIG. 8, the first bent portion 36 is the entirety of the whole connecting beam 35. In another embodiment, the first bent portion 36 may be arranged to be part of the connecting beam 35. Also, straight segments, curved segments, or the like are arranged at two sides of the first bent portion 36. However, regardless of the methods of arranging the first bent portion 36, a T-shaped rod structure is provided according to the embodiments of the present disclosure due to inclusion of the first bent portion 36. With the first bent portion 36, a tensile stress of the connecting beam is unlikely to rapidly increase when the connecting beam 35 receives a force in a direction opposite to a protrusion direction of the first bent portion 36 and a large displacement occurs. Therefore, the first bent portion 36 is prevented from fracturing the connecting beam 35 in response to rapidly reaching a fracture stress of silicon, providing the connecting beam 35 with resistance to fracture.

In addition, this design scheme with the first bent portion 36 also allows for an addition of a second-order non-linear term to the recovery coefficient of the coupling spring to meet demands in some application scenarios. In an exemplary embodiment of the present disclosure, as shown in FIG. 8, a left half of the connecting beam 35, i.e., a shape of a 0<x<L/2, segment, can be expressed as:

$${y}_{0} = \frac{{a}_{1} x}{L} + \frac{{a}_{2} {x}^{2}}{{L}^{2}} + \frac{{a}_{3} {x}^{3}}{{L}^{3}} .$$

A right half of L/2<x<L also has a symmetric shape, where a₁, a₂, and a₃ are predetermined constants related to an initial shape of the connecting beam.

Therefore, it can be deduced that a relationship between a restoring force F and a deformation x can be expressed by the following equation:

$$F = kx + {k}_{2} {x}^{2} + {k}_{3} {x}^{3} , where$$

$$k = \frac{192 EI + {EAa}^{2}}{{L}^{3}} ,$$

$${k}_{2} = \frac{36 EAa}{{L}^{3}} , and$$

$${k}_{3} = \frac{288 EA}{25 {L}^{3}} .$$

In the above-mentioned equations,

$$a = 2 {a}_{1} + {a}_{2} + \frac{9}{20} {a}_{3} ,$$

where E represents a modulus of elasticity, I represents a moment of inertia of a cross-section of the connecting beam, A represents a cross-sectional area of the connecting beam, and L represents a length of the connecting beam.

The above-mentioned relationship between the restoring force F and the deformation x reveals that the recovery coefficient includes a second-order non-linear term related to a shape of the connecting beam. The second-order non-linear term indicates that the restoring force of the connecting beam 35 having the first bent portion 36 is asymmetric during a deformation. A controllable non-linear term is also realized by the embodiments of the present disclosure.

Another implementation may be as shown in FIG. 9. Compared with the connecting rod 34 in FIG. 8, the connecting rod 34 in FIG. 9 is free. In the embodiments of the present disclosure, the above-mentioned fixing pile 21 and the first beam structure 22 may be further arranged at the connecting rod 34. For the spring assembly arranged at the MEMS system, the above-mentioned fixing pile 21 may be arranged at the body of the MEMS system.

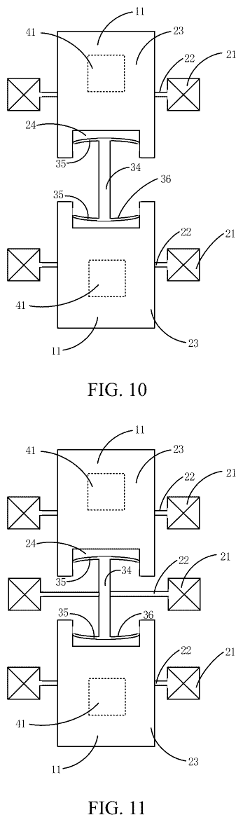

In some embodiments, a drive unit may be provided to drive the torsion spring to twist. In an exemplary embodiment of the present disclosure, as shown in FIG. 10, a drive unit 41 may be further arranged at the MEMS, in such a manner that the drive unit 41 is configured to drive at least one of the above-mentioned two torsion springs 11 to twist. The drive unit 41 includes, but is not limited to, any one of an electrostatic drive unit, an electrothermal drive unit, a capacitive drive unit, or a piezoelectric drive unit. By arranging any one of the above-mentioned drive units 41 at the MEMS, a technical effect of driving the torsion spring 11 to twist can be achieved. A set position of the drive unit in FIG. 10 is only an example and can be selected as desired based on actual demands and different operation methods.

In some embodiments, a respective drive unit 41 may be provided for each torsion spring 11. Each drive unit 41 is configured to drive the torsion spring 11 corresponding to the drive unit 41 to twist. The above-mentioned drive unit 41 can be configured to drive, based on demands, the torsion springs 11 to twist in a time-sharing manner or to twist synchronously. In particular, in the application scenario of the above-mentioned MEMS reflection mirror, it is preferred that the drive unit 41 is configured to drive the torsion springs 11 to twist synchronously, in such a manner that small-area reflection mirrors arranged thereon can also rotate synchronously, achieving a result of forming a large-area scanning mirror by using the small-area reflection mirrors.

Another implementation may be as shown in FIG. 11. Compared with the connecting rod 34 in FIG. 10, the connecting rod 34 in FIG. 11 is free. In the embodiments of the present disclosure, the above-mentioned fixing pile 21 and the first beam structure 22 may be further arranged at the connecting rod 34. For the spring assembly arranged at the MEMS system, the above-mentioned fixing pile 21 may be arranged at the body of the MEMS system.

According to the embodiments of the present disclosure, the scanning mirror is further provided, which is based on the MEMS system and can be applied to the LiDAR system. FIG. 12 is a schematic structural view of a scanning mirror according to an embodiment of the present disclosure. As shown in FIG. 12, the scanning mirror includes torsion springs 51 arranged in an array on a MEMS. The coupling spring 52 is arranged between any two adjacent torsion springs of the torsion springs 51. Two ends of the coupling spring 52 are connected to the two adjacent torsion springs 51, respectively. In response to the two adjacent torsion springs 51 being twisted, the coupling spring 52 is stretched to provide a torque that is non-linearly recovered.

The above-mentioned any two adjacent torsion springs 51 and the coupling spring 52 arranged between the two adjacent torsion springs 51 form the spring assembly, and thus reference to details thereof can be made to the above-mentioned embodiments shown in FIG. 2 to FIG. 11.

In the embodiments of the present disclosure, in conjunction with FIG. 2 to FIG. 11, each torsion spring 51 includes two fixing piles arranged opposite to each other and a beam structure arranged between the two fixing piles. The first beam structure is provided with a first connecting plate. In addition, the two ends of the coupling spring 52 in a stretching direction are connected to two first connecting plates of the two torsion springs, respectively. The reflection mirror is arranged at a surface of the first connecting plate.

In the embodiments of the present disclosure, a plurality of torsion springs 51 are arranged at the MEMS in the array. That is, torsion springs 51 in a plurality of rows and columns can be included. In addition, the reflection mirror is arranged at the surface of the first connecting plate of each torsion spring 51, in such a manner that the large-area reflection mirror can be formed by the plurality of small-area reflection mirrors mentioned above.

In some embodiments, such as the embodiment shown in FIG. 12, a drive component may further be provided. The drive component is configured to drive the torsion springs arranged in the array to twist synchronously. Driving the torsion springs arranged in the array to twist synchronously is equivalent to driving the large-area scanning mirror to rotate, realizing that light reflected from the large-area scanning mirror can be scanned in a predetermined region.

Operation principles and a set position of the drive component are not limited in the embodiments of the present disclosure. The drive component may include various forms of drive components. For example, the drive component may be independently arranged at a MEMS substrate or may be arranged at the MEMS substrate and the first connecting plate. In addition, to save a space and to reserve a space for the reflection mirror at the first connecting plate, other members may be arranged below the first connecting plate as a whole.

In addition, the above-mentioned drive component may include a plurality of drive units. Each of the plurality of drive units is arranged corresponding to one of the torsion springs and is configured to drive the respective torsion spring to twist. Depending on operation principles, the drive unit includes, but is not limited to, any one of the electrostatic drive unit, the electrothermal drive unit, the capacitive drive unit, or the piezoelectric drive unit. By arranging any one of the above-mentioned drive units at the MEMS, the technical effect of driving the torsion spring to twist can be achieved. In some embodiments, to realize an effective connection between the coupling spring and the first connecting plate, the end of the first connecting plate close to the coupling spring has the opening. The coupling spring includes the connecting rod and the two connecting beams arranged at the two ends of the connecting rod, respectively. The connecting rod is connected to parts of each of the two first connecting plates arranged at the two sides of the opening by the two connecting beams, respectively. In particular, reference can be made to the above-mentioned embodiment shown in FIG. 6. In another embodiment, the second connecting plate is arranged at the coupling spring. The second connecting plate has an opening and is provided with a beam structure. The second connecting plate is connected to the first connecting plate by the beam structure. Reference to details thereof can be made to the above-mentioned embodiment shown in FIG. 4. The technical solution of forming the opening at the first connecting plate of the torsion spring, compared with the technical solution of forming the opening at the second connecting plate of the coupling spring, can make the coupling spring small in size and more space be reserved for accommodating the first connecting plate, in such a manner that the area of the reflection mirror at the first connecting plate is enlarged, enlarging the effective reflection area of the MEMS scanning mirror.

In addition, in some embodiments, to enlarge the area of each reflection mirror, and to enlarge the area of the scanning mirror that is ultimately formed, the above-mentioned first connecting plate may be expanded in a column direction to enable the coupling spring to be located in a gap formed by the above-mentioned first connecting plate. In this case, a vast majority of the area of the surface of the entire MEMS system is occupied by the scanning mirror that is ultimately formed to further enlarge the effective reflective area of the MEMS scanning mirror, and to improve uniformity of reflected light.

Further, in another embodiment, for the torsion springs 51 in different columns in FIG. 12, the torsion springs 51 in one column may be connected to the torsion springs 51 in another column adjacent to the one column and located in a same row. That is, as in the above-mentioned embodiments shown in FIG. 4 to FIG. 11, any first connecting plate 23 is connected to the first connecting plate 23 of another torsion spring 51 in the same row and an adjacent column, as long as the fixing pile 21 is avoided. Such an implementation can further enlarge the area of the reflection mirror at the first connecting plate 23 to further enlarge the effective reflective area of the MEMS scanning mirror, and to improve the uniformity of the reflected light.

In addition, in the embodiments of the present disclosure, the connecting beam in the coupling spring includes a bent portion. For example, the above-mentioned first bent portion protrudes in a direction away from the connecting rod. Reference to details thereof can be made to the above-mentioned embodiment shown in FIG. 8. Since the first bent portion is arranged, the tensile stress of the connecting beam is unlikely to rapidly increase even when the large displacement occurs in the direction opposite to the protrusion direction of the first bent portion. Therefore, the first bent portion is prevented from fracturing the connecting beam in response to rapidly reaching the fracture stress of silicon, providing the first bent portion with the resistance to fracture. In addition, such a design also causes the recovery coefficient of the connecting beam to include the second-order non-linear recovery coefficient, which is conducive to ultimately realizing the controllable non-linear spring demanded by the technical solutions of the present disclosure and facilitates subsequent synchronous control of synchronous torsion of the plurality of reflection mirrors mentioned above.

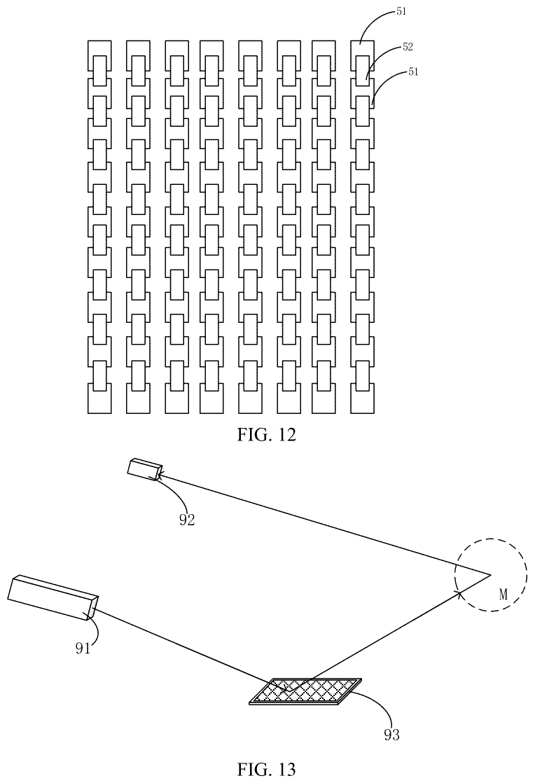

The LiDAR system is further provided according to the embodiments of the present disclosure. The LiDAR system can realize light detection and ranging. FIG. 13 is a schematic structural view of a LiDAR system according to an embodiment of the present disclosure. As shown in FIG. 13, the LiDAR system includes a light source 91, a photodetector 92, and the above-mentioned scanning mirror 93. A laser beam emitted by the light source 91 is reflected to a target region M by the above-mentioned scanning mirror 93. In addition, the photodetector 92 is configured to receive at least part of reflected light from the target region M and convert the at least part of the reflected light into an electrical signal. Further, a processor may be provided. The processor is configured to obtain a laser point cloud from the target region based on the electrical signal output by the photodetector 92. The light detection and ranging can be realized based on the above-mentioned laser point cloud.

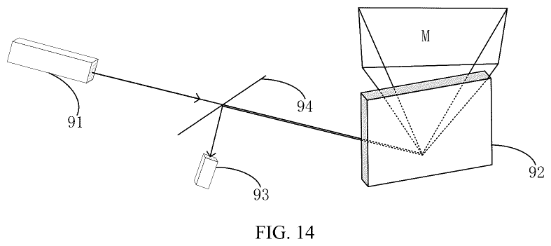

FIG. 14 is a schematic structural view of another LiDAR system according to an embodiment of the present disclosure. As shown in FIG. 14, the LiDAR system also includes the light source 91, the photodetector 92, and the scanning mirror 93, with a difference that, unlike a paraxial technical solution adopted in FIG. 13, a coaxial technical solution is adopted in the embodiment shown in FIG. 14. In an exemplary embodiment of the present disclosure, the LiDAR system further includes a beam splitter 94. In this way, the laser beam emitted by the light source 91 is reflected by the scanning mirror 93 to the target region M after sequentially passing through the beam splitter 94 and the scanning mirror 93, for scanning the target region M. The at least part of the reflected light from the target region M may pass through the above-mentioned scanning mirror 93 to the beam splitter 94. The reflected light is directed to the photodetector 92 by the beam splitter 94 to enable the photodetector 92 to convert the reflected light into an electrical signal. Further, the processor can be configured to obtain the laser point cloud from the target region based on the electrical signal output from the photodetector, where the processor is further provided in the system, to realize the light detection and ranging. The above-mentioned light source 91, the photodetector 92, and the beam splitter 94 according to this embodiment may also form a laser transceiver module to realize laser emission and detection.

Due to the use of the scanning mirror according to the above-mentioned embodiments, the LiDAR system according to the embodiments of the present disclosure has corresponding technical effects and advantages. In addition, the above-mentioned LiDAR system can be applied to a vehicle. A solution of forming the scanning mirror by the plurality of small-area reflection mirrors is conducive to improving a vibration-resistant capability of the LiDAR system during vehicle operation.

In addition, in the LiDAR system according to the embodiments of the present disclosure, synchronous torsion of individual reflection mirrors in the scanning mirror enables scanning to be performed after the laser beam is reflected to the target region M. This scanning method, however, performs scanning in a predetermined direction. For enlarging an area of the target region M, the scanning also needs to be performed in a vertical direction. That is, for an XY coordinate system in the target region M, scanning along an X-axis rather than a Y-axis can be achieved using the technical solutions according to the embodiments of the present disclosure. Therefore, in some embodiments, the drive component may further be provided, which can be configured to directly drive the scanning mirror as a whole to move back and forth in a reciprocating manner to achieve scanning along the Y-axis. The above-mentioned drive component may be a drive motor. The drive motor is configured to directly drive, using an output shaft, the scanning mirror to reciprocate, to ultimately realize scanning performed by the reflected light from the scanning mirror along the Y-axis. In this case, the output shaft of the drive motor usually needs to be able to steer in time, switching between a forward rotation and a reverse rotation. Or, in an alternative technical solution, a movement adjustment member may be provided, which is capable of converting a continuous circular movement of the output shaft of the drive motor into a cyclic reciprocating movement. The scanning mirror is driven by the movement adjustment member to perform a periodic reciprocating movement, to ultimately realize the scanning performed by the reflected light from the scanning mirror along the Y-axis.

For the scanning mirror, according to the embodiments of the present disclosure, scanning realized by driving each small-area scanning mirror inside the scanning mirror can be at a relatively high scanning frequency. That is, rapid scanning along the X-axis in the target region M is achieved. However, scanning realized by driving, using the drive motor, the entire scanning mirror can be at a relatively low scanning frequency. That is, low scanning along the Y-axis in the target region M is achieved.

Terms such as “first” and “second” in the specification of the present disclosure and the appended claims are used only to distinguish between similar objects, rather than to describe a particular order or sequence. It should be understood that the data as used can be interchanged where appropriate, to enable the embodiments of the present disclosure described herein to be implemented in an order other than that illustrated or described herein. Also, the objects distinguished by the terms such as “first” and “second” are usually objects of the same type. The quantity of the objects is not limited. For example, one or a plurality of first objects may be provided. In addition, “and/or” throughout the specification and appended claims indicates at least one of the objects associated with “and/or”. The character “/” generally indicates that the associated objects before and after the character are in an “or” relationship.

In the description of the present disclosure, it should be understood that, the orientation or the position indicated by terms such as “center”, “longitudinal”, “lateral”, “length”, “width”, “thickness”, “over”, “below”, “front”, “rear”, “left”, “right”, “vertical”, “horizontal”, “top”, “bottom”, “inner”, “outer”, “clockwise”, “anti-clockwise”, “axial”, “radial”, and “circumferential” should be construed to refer to the orientation and the position as shown in the drawings, and is only for the convenience of describing the present disclosure and simplifying the description, rather than indicating or implying that the pointed device or element must have a specific orientation, or be constructed and operated in a specific orientation, and therefore cannot be understood as a limitation of the present disclosure.

In the description of the present disclosure, “first feature” and “second feature” may include one or more of these features.

In the description of the present disclosure, “plurality” means two or more.

In the description of the present disclosure, the first feature “on” or “under” the second feature may mean that the first feature is in direct contact with the second feature, or the first and second features are in indirect contact through another feature between them.

In the description of the present disclosure, the first feature “above” the second feature means that the first feature is directly above or obliquely above the second feature, or simply means that the level of the first feature is higher than that of the second feature.

Reference throughout the present disclosure to “an embodiment”, “some embodiments”, “exemplary embodiments”, “an example”, “a specific example”, or “some examples” means that a particular feature, structure, material, or characteristic described in connection with the embodiment or example is included in at least one embodiment or example of the present disclosure. The appearances of the above phrases in various places throughout this specification are not necessarily referring to the same embodiment or example. Further, the particular features, structures, materials, or characteristics may be combined in any suitable manner in one or more embodiments or examples.

Although embodiments of the present disclosure have been illustrated and described, it is conceivable for those skilled in the art that various changes, modifications, replacements, and variations may be made to these embodiments without departing from the principles and spirit of the present disclosure. The scope of the present disclosure shall be defined by the claims as appended and their equivalents.

What is claimed is:

1. A spring assembly, comprising:
two torsion springs; and
a coupling spring arranged between the two torsion springs, two ends of the coupling spring being connected to the two torsion springs, respectively, and in response to the two torsion springs being twisted, the coupling spring being stretched to provide a torque that is non-linearly recovered.

2. The spring assembly according to claim 1, wherein each of the two torsion springs comprises two fixing piles arranged opposite to each other and a first beam structure arranged between the two fixing piles, the first beam structure being provided with a first connecting plate, and the two ends of the coupling spring in a stretching direction being connected to two first connecting plates of the two torsion springs, respectively.

3. The spring assembly according to claim 2, wherein in response to the two torsion springs being twisted, the first connecting plate is rotatable around a connection line between the two fixing piles arranged opposite to each other.

4. The spring assembly according to claim 2, wherein the coupling spring comprises a second connecting plate that is overhung, each of two ends of the second connecting plate having a first opening, a second beam structure being formed in the first opening, and the first connecting plate being connected to the second connecting plate by the second beam structure.

5. The spring assembly according to claim 2, wherein:
an end of each of the two first connecting plates close to the coupling spring has a second opening;
the coupling spring comprises a connecting rod and a connecting beam arranged at two ends of the connecting rod; and
two ends of the connecting rod are connected to the two first connecting plates arranged at two sides of the second opening by the connecting beam, respectively.

6. The spring assembly according to claim 5, wherein the connecting beam comprises a first bent portion protruding in a direction away from the connecting rod.

7. The spring assembly according to claim 1, further comprising a drive unit configured to drive at least one of the two torsion springs to twist.

8. The spring assembly according to claim 7, wherein two drive units are provided for the two torsion springs, respectively, the two drive units being configured to drive the two torsion springs to twist, respectively.

9. The spring assembly according to claim 1, wherein a degree of non-linearity of the spring assembly is adjustable by adjusting the length of each of the two torsion springs, a length of the coupling spring, and a recovery coefficient of the coupling spring.

10. A scanning mirror, comprising:
at least one spring assembly, each of the at least one spring assembly comprising:
two torsion springs; and
a coupling spring arranged between the two torsion springs, two ends of the coupling spring being connected to the two torsion springs, respectively, and in response to the two torsion springs being twisted, the coupling spring being stretched to provide a torque that is non-linearly recovered; and
a reflecting mirror arranged at each of the at least one spring assembly.

11. The scanning mirror according to claim 10, wherein each of the two torsion springs comprises two fixing piles arranged opposite to each other and a first beam structure arranged between the two fixing piles, the first beam structure being provided with a first connecting plate, and the two ends of the coupling spring in a stretching direction being connected to two first connecting plates of the two torsion springs, respectively, the reflecting mirror being arranged at a surface of each of the two first connecting plates.

12. The scanning mirror according to claim 11, wherein in response to the two torsion springs being twisted, the first connecting plate is rotatable around a connection line between the two fixing piles arranged opposite to each other.

13. The scanning mirror according to claim 11, wherein the coupling spring comprises a second connecting plate that is overhung, each of two ends of the second connecting plate having a first opening, a second beam structure being formed in the first opening, and the first connecting plate being connected to the second connecting plate by the second beam structure.

14. The scanning mirror according to claim 11, wherein:
an end of each of the two first connecting plates close to the coupling spring has a second opening;
the coupling spring comprises a connecting rod and a connecting beam arranged at two ends of the connecting rod; and
two ends of the connecting rod are connected to the two first connecting plates arranged at two sides of the second opening by the connecting beam, respectively.

15. The scanning mirror according to claim 14, wherein the connecting beam comprises a first bent portion protruding in a direction away from the connecting rod.

16. The scanning mirror according to claim 10, wherein each of the at least one spring assembly further comprises a drive unit configured to drive at least one of the two torsion springs to twist.

17. The scanning mirror according to claim 16, wherein two drive units are provided for the two torsion springs, respectively, the two drive units being configured to drive the two torsion springs to twist, respectively.

18. The scanning mirror according to claim 10, wherein the at least one spring assembly comprises a plurality of spring assemblies arranged in an array.

19. The scanning mirror according to claim 10, wherein reflecting material is coated on the surface of each of the two first connecting plates to form the reflecting mirror.

20. A LiDAR system, comprising:
a light source;
a photodetector;
a processor; and
the scanning mirror according to claim 10, wherein:
a laser beam emitted by the light source is reflected to a target region by the scanning mirror;
the photodetector is configured to receive at least part of reflected light from the target region and convert the at least part of the reflected light into an electrical signal; and
the processor is configured to obtain a laser point cloud from the target region based on the electrical signal.
